(19) United States
(12) Patent Application Publication
(10) Pub. No.: US 2011/0164955 A1
(43) Pub. Date: Jul. 7, 2011

(54) PROCESSING CHAMBER WITH TRANSLATING WEAR PLATE FOR LIFT PIN

(75) Inventors: John M. White, Hayward, CA (US); Jeonghoon Oh, San Jose, CA (US); Tom K. Cho, Los Altos Hills, CA (US); Silja James, Mountain View, CA (US); Uday Pai, San Jose, CA (US); Oscar Lopez, Watsonville, CA (US); Alexander S. Polyak, San Jose, CA (US)

(73) Assignee: APPLIED MATERIALS,INC., Santa Clara, CA (US)

(21) Appl. No.: 12/835,511

(22) Filed: Jul. 13, 2010

Related U.S. Application Data
(60) Provisional application No. 61/234,514, filed on Aug. 17, 2009.
(60) Provisional application No. 61/225,617, filed on Jul. 15, 2009.

(51) Int. Cl. H01L 21/683; F16M 11/00

(52) U.S. Cl. 414/800; 248/346.01

(57) ABSTRACT

Embodiments of a method and apparatus for processing large area substrates including a translational wear plate and/or bushing assembly are provided for reducing the stress on a lift pin used to space substrates from a substrate support in a processing or other type of chamber. In another embodiment, an apparatus for processing substrates includes processing chamber comprising a substrate support disposed in a chamber body. A bushing assembly is disposed in the substrate support. A lift pin is disposed through the bushing assembly. A wear plate is provided that is coupled to the chamber body and aligned with the lift pin. The wear plate is movable laterally relative to a centerline of the chamber body to accommodate lateral motion of the lift pin when contacting the wear plate.

### CROSS REFERENCE TO RELATED APPLICATIONS

This application claims benefit of U.S. Provisional Patent Application Ser. No. 61/234,514, filed Aug. 17, 2009 and U.S. Provisional Patent Application Ser. No. 61/225,617, filed Jul. 15, 2009. All of the above referenced patent applications are incorporated by reference in their entireties.

### BACKGROUND OF THE INVENTION

1. Field of the Invention

Embodiments of the invention generally relate to a substrate processing system, and more specifically, to a substrate processing system having improved lift pin actuation.

2. Description of the Related Art

Large area substrates are typically utilized in the manufacture of flat panel displays, PDA's, TFT's, photovoltaic devices, and other products. As the size of large area substrates has increased, the size of the equipment utilized to process large area displays has correspondingly increased. With the increased equipment size, maintaining the lift pins utilized to lift the substrate in a vertically aligned orientation during substrate transfer has become increasingly difficult. The increased weight of large area substrates subjects lift pins and lift pin guiding mechanisms that are out of vertical alignment to a substantial increase in wear. This is particularly important in the manufacture of solar devices due to the relatively higher weight of photovoltaic devices. Wear produces unwanted particles which may result in the contamination of the structures being formed on the large area substrates. Moreover, high wear rates require more frequent maintenance intervals and part replacement, thereby reducing system throughput and increasing the cost of ownership. Moreover, should the lift pin mechanism fail, expensive substrate damage may result.

Therefore, there exists a need for an improved lift pin actuation system.

### SUMMARY OF THE INVENTION

Embodiments of a method and apparatus for processing large area substrates including a translational wear plate and/or bushing assembly are provided for reducing the stress on a lift pin used to space substrates from a substrate support in a processing or other type of chamber. In another embodiment, an apparatus for processing substrates includes a processing chamber having a substrate support disposed in a chamber body. A bushing assembly is disposed in the substrate support. A lift pin is disposed through the bushing assembly. A wear plate is provided that is coupled to the chamber body and aligned with the lift pin. The wear plate is movable laterally relative to a centerline of the chamber body to accommodate lateral motion of the lift pin when contacting the wear plate.

In another embodiment, an apparatus for processing substrates includes a processing chamber having a substrate support disposed in a chamber body. A bushing assembly is disposed in the substrate support. A lift pin is disposed through the bushing assembly. The bushing assembly includes a plurality of spaced-apart bushings snap-fit into a central bore of a cylindrical body. The spaced-apart bushings reduce stress induced on the lift pin when the lift pin has a lateral force exerted thereon.

In yet another embodiment, a method for spacing a substrate from a substrate support is provided that includes lowering a substrate support to contact distal ends of lift pins to a laterally movable wear plate, and further lowering the substrate support to project heads of the lift pins contacting the wear plate from an upper surface of the substrate support.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 is a sectional view of one embodiment of a processing chamber having a floating lift pin contact pad;

FIG. 2 is a partial sectional view of the processing chamber of FIG. 1 illustrating an enlarged view of the floating lift pin contact pad;

FIG. 3 is a top view of one embodiment of a flexure;

FIG. 4 is another embodiment of a floating lift pin contact pad;

FIG. 5 is another embodiment of a floating lift pin contact pad;

FIG. 6 is a partial sectional view of a processing chamber having another embodiment of a floating lift pin contact pad;

FIGS. 7 and 8 are sectional and bottom views of one embodiment of a bushing assembly (i.e., lift pin guide);

FIG. 9 is an isometric view of one embodiment of a bushing;

FIG. 10A is a top view of another embodiment of floating lift pin contact pad attached to a processing chamber;

FIG. 10B is a cross-sectional view of the floating lift pin contact pad along Section A-A shown in FIG. 10A.

FIGS. 11-14 are partial cross-sectional views of a processing chamber depicting the floating lift pin contact pad shown in FIGS. 10A and 10B depicting its operation in use.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments described herein generally provide a method and apparatus for processing large area substrates, which is particularly suitable for large area substrates having a plan area greater than one square meter, such as greater than about two square meters or larger. It is also contemplated that the invention may be utilized with smaller substrates, such as semiconductor wafers or other workpieces. In one embodiment, the apparatus for processing large area substrates includes a translational wear plate for reducing the stress on a lift pin used to space the large area substrates from a substrate support in a processing or other type of chamber. In another embodiment, the apparatus for processing large area substrates includes a bushing assembly for reducing the stress on the lift pin used to space the large area substrates from the substrate support. The translational wear plate and/or bushing assembly may be used in a vacuum deposition chamber adapted to deposit materials on the media to form electronic devices such as thin film transistors, organic light emitting diodes, photovoltaic devices or solar cells, including chemical vapor deposition chambers and physical vapor deposition chambers. The translational wear plate and/or bushing assembly may also be used in load lock chambers, etching chambers or other applications where lift pins are utilized.

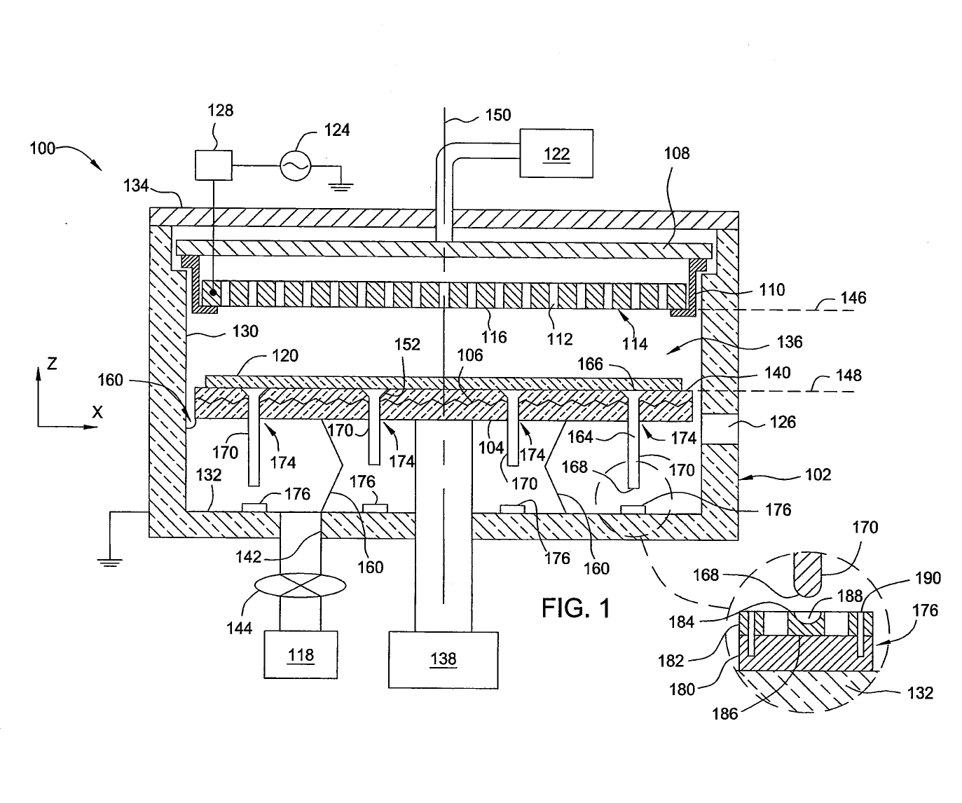

FIG. 1 is a schematic cross-sectional view of one embodiment of a processing system 100. In one embodiment, the processing system 100 is configured to process a large area substrate, such as a large area substrate 120, using a high density plasma chemical vapor deposition (PECVD) process to form portions of structures and devices on the large area substrate 120. The structures formed by the processing system 100 may be adapted for use in the fabrication of liquid crystal displays (LCD's), thin film transistors (TFT), flat panel displays, organic light emitting diodes (OLED's), and photovoltaic cells for solar cell arrays, among others. The substrate 120 may be a thin sheet of metal, plastic, organic material, silicon, glass, quartz, or polymer, among other suitable materials. The substrate 120 may have a surface area greater than about 1 square meter, such as greater than about 2 square meters. It is also contemplated that the processing system 100 may be adapted to process substrates of other sizes and types, and may be used to fabricate other structures.

The processing system 100 includes a chamber body 102, a gas panel 122 and a power source 124. The chamber body 102 is grounded and includes sidewalls 130, a bottom 132 and a lid 134 enclosing an internal volume 136. A sealable slit valve passage 126 and a pumping port 142 are formed though the chamber body 102. The slit valve passage 126 allows entry and egress of the substrate 120 from the internal volume 136 of the chamber body 102. The pumping port 142 is coupled to a pumping system 118 to evacuate the internal volume 136. A throttle valve 144 may be disposed between the pumping system 118 and the pumping port 142 to control the pressure within the internal volume 136.

A showerhead assembly 114 and a substrate support 104 are disposed in the internal volume 136 of the chamber body 102. In one embodiment, the showerhead assembly 114 includes a face plate 116, a suspension 110 and a backing plate 108. The face plate 116 includes a plurality of apertures 112 for distributing gas provided from the gas panel 122 within the internal volume 136 of the chamber body 102. The suspension 110 couples the face plate 116 to the backing plate 108. The backing plate 108 is utilized to control the sag of the face plate 116.

In many applications, a plane of the face plate 116, indicated by imaginary line 146, is substantially perpendicular to a vertical centerline 150 of the chamber body 102. In some applications, the plane of the face plate 116, indicated by imaginary line 146, is oriented at an acute angle relative to the vertical centerline 150 of the chamber body 102. In applications wherein the plane of the face plate 116 is not horizontal, the substrate support 104 may optionally be inclined such that a plane of an upper surface 140 of the substrate support 104, indicated by imaginary line 148, is disposed at an acute angle relative to the vertical centerline 150 of the chamber body 102, thereby orientating the plane of the upper surface 140 of the substrate support 104 parallel to the plane of the face plate 116.

The showerhead assembly 114 may be coupled to the RF power source 124 to energize gases within the internal volume 136. In one embodiment, the RF power source 124 is coupled to the face plate 116 through a matching circuit 128. The RF power source 124 may be utilized to form and/or maintain a plasma of gases provided from the gas panel 122 in a region of the internal volume 136 defined between the substrate support 104 and face plate 116 during processing of the substrate 120 and/or cleaning of the chamber body 102. In one embodiment, the substrate support 104 is electrically conductive and adapted to function as a shunt electrode to facilitate a RF return path for RF energy.

The showerhead assembly 114 and the lid 134 may be formed from electrically conductive materials and are in electrical communication with one another. The chamber body 102 is also formed from an electrically conductive material and is electrically insulated from the showerhead assembly 114.

In another embodiment, a plurality of RF return devices 160 may be coupled between the substrate support 104 and the sidewall 130 and/or the bottom 132 of the chamber body 102. Each of the RF return devices 160 couple the substrate support 104 to ground. Alternatively or additionally, the RF return devices 160 may provide a portion of an RF return path back to the RF power source 124. In this embodiment, returning RF current will pass from the substrate support 104 through the RF return devices 160 to the interior surface of the bottom 132 and/or sidewalls 130 to return to the RF power source 124.

The substrate support 104 is adapted to support the substrate 120 on the upper surface 140 during processing. The substrate support 104 may also include a temperature control device 106. The temperature control device 106 is utilized to control the temperature of the substrate support 104 and substrate 120 disposed thereon. The temperature control device 106 may be conduits for circulating a heating and/or cooling fluid. The temperature control device 106 alternatively may be a resistive heater.

A lift mechanism 138 is configured to the substrate support 104 and utilized to control the elevation of the substrate support 104 within the internal volume 136. The substrate support 104 is elevated proximate the showerhead assembly 114 during processing and lowered proximate a slit valve passage 126 formed through one of the sidewalls 130 during substrate transfer.

A plurality of lift pins 170 extend through bushing assemblies (i.e., guides 174) disposed in lift pin holes 152 formed through the substrate support 104. The lift pins 170 are utilized to space the substrate 120 from the upper surface 140 of the substrate support 104 to facilitate robotic transfer of the substrate 120 to and from the substrate support 104. The lift pins 170 include a head 166 and a distal end 168. The head 166 may be flared or otherwise greater in diameter than a shaft 164 of the lift pin 170 such that the lift pin 170 can not fall through the substrate support 104. The distal ends 168 of the lift pins 170 extend below the substrate support 104 so that the lift pins 170 contact the chamber bottom 132 (or wear plate 176) to cause the heads 166 of the lift pins 170 to extend from the upper surface 140 of the substrate support 104 as the substrate support 104 lowers, thus spacing the substrate 120 from the upper surface 140 to facilitate substrate transfer. Optionally, the inner lift pins 170 may be shorter than the outer lift pins 170 so that the substrate 120 is spaced from the upper surface 140 in a concave orientation.

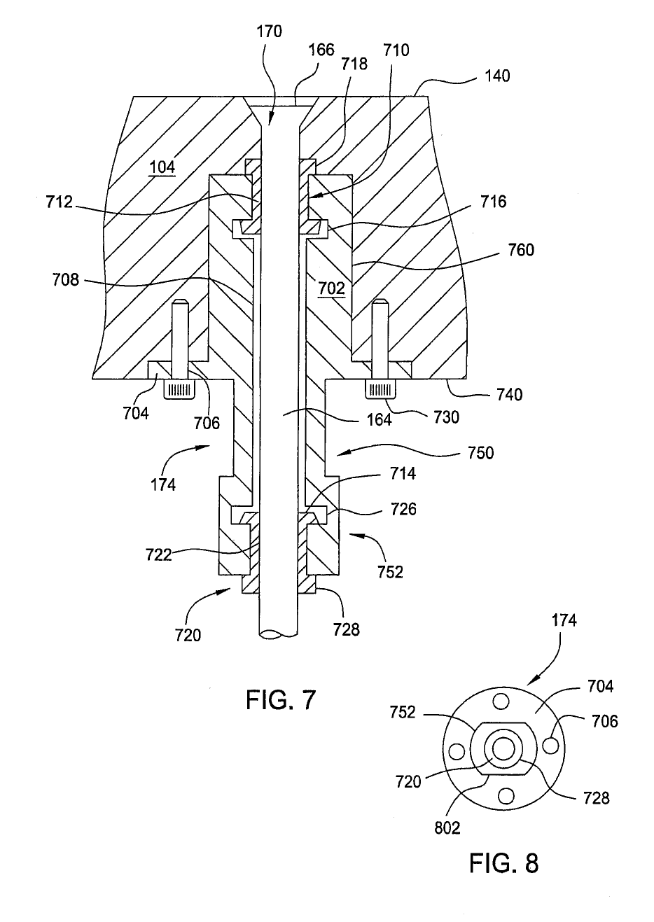

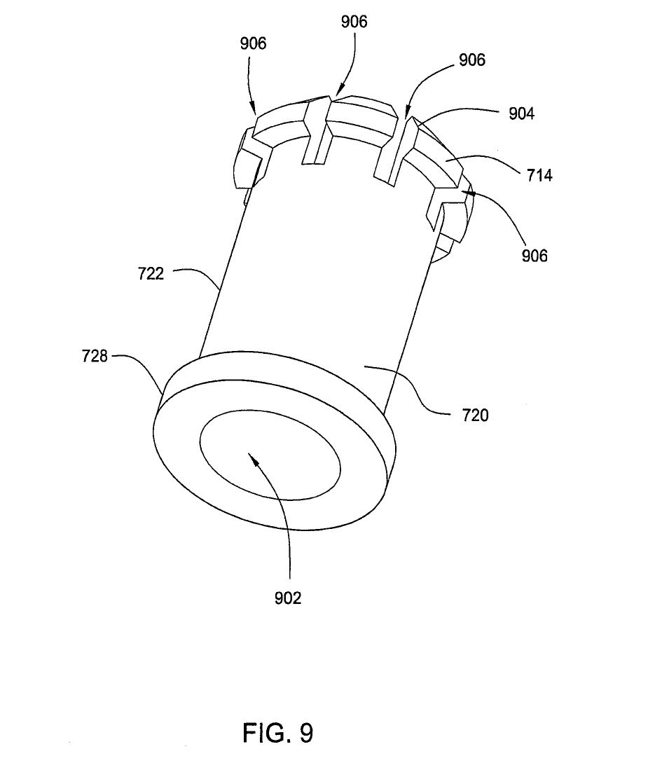

In one embodiment, the guide 174 for the lift pins 170 is a roller bushing. When roller bushings are utilized as the guide 174, a dry lubricant or polymer sleeve around the roller axis may be utilized to improve roller/axle life and bearing function. One suitable dry lubricant is a graphite-based lubricant. In another embodiment, the guide 174 includes a plurality of solid, stationary bearing surfaces, as further described below with reference to FIGS. 7-8.

Use of the wear plate 176 has been demonstrated to extend the lift of the lift pin 170. Each wear plate 176 is coupled to the bottom 132 of the chamber body 102 directly below a respective lift pin 170. In one embodiment the wear plate 176 includes a base plate 180 and a contact plate 182. The base plate 180 may be coupled to the bottom 132 of the chamber body 102 in any suitable manner. The contact plate 182 may be coupled to the base plate 180 in any suitable manner, and in the embodiment depicted in FIG. 1, the contact plate 182 may be coupled to the base plate 180 by a plurality of fasteners 190. The base plate 180 and the contact plate 182 are fabricated from materials that allow the contact plate 182 to slide readily over the base plate 180. In one embodiment, the base plate 180 is aluminum, stainless steel or ceramic, while the contact plate 182 is a polymer, such as a fluoropolymer or polyethylene.

The contact plate 182 includes a first surface 184 and a second surface 186. The second surface 186 of the contact plate 182 contacts the base plate 180 and is adapted to readily slide thereover. The first surface 184 of the contact plate 182 may optionally include a recess 188 for receiving the distal end 168 of the lift pin 170. The recess 188 may be spherical to minimize particle generation when contacted with the rounded distal end 168 of the lift pin 170 and to ensure that most of the translation motion is between the plates 180, 182 and not between the lift pins 170 and contact plate 182.

The portion of the contact plate 182 containing the recess 188 is configured to slide laterally relative to the base plate 180. This enables the distal end 168 of the lift pin 170 to translate relative to the bottom 132 of the chamber body 102 when the substrate support 104 is lowered to cause the heads 166 of the lift pins 170 to extend from the upper surface 140 of the substrate support 104. Thus, if the substrate support 104 is sagging such that the upper surface 140 is curved or that the centerline line of the substrate support is disposed at an acute angle relative to the centerline 150 of the processing system 100 resulting in non-verticality of the lift pins 170, the distal ends 168 of the lift pins 170 may move laterally when in contact with the wear plate 176 with little resistance such that stress between the shaft 164 of the lift pins 170 and the guide 174 is substantially reduced over conventional lift pin actuation arrangements. The reduced wear on the guide 174 and shaft 164 of the lift pins 170 greatly extends the life of both the lift pin 170 and guide 174, which extends the maintenance interval and significantly reduces the cost of ownership, particle generation and potential damage to the substrate. The wear plat 176 may also include one or more biasing members which return the contact plate 182 to a centered position once a displacing force is removed.

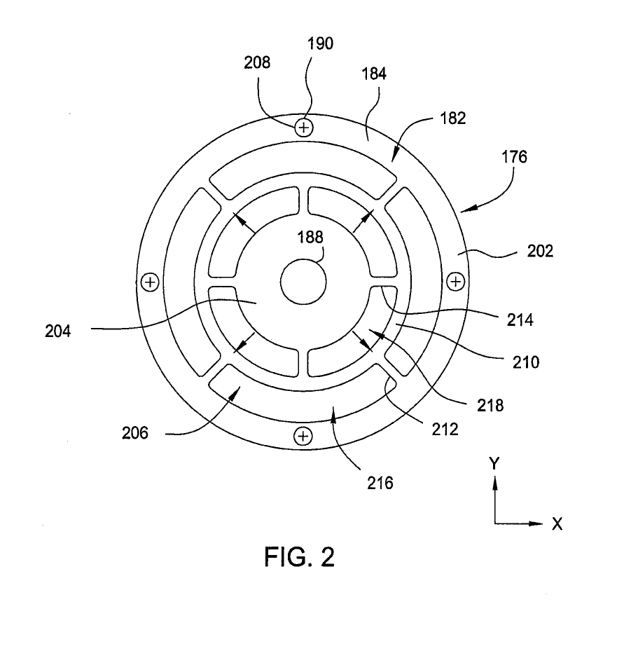

FIG. 2 is a top view of the wear plate 176. In the embodiment depicted in FIG. 2, the contact plate 182 includes an outer ring 202, a disk 204 and a biasing member, shown here as a flexure 206. The outer ring 202 circumscribes the disk 204. The disk 204 includes the recess 188 on its upper surface and is coupled to the outer ring 202 by the flexure 206. The outer ring includes a plurality of mounting holes 208 which accommodate the fasteners 190 coupling the contact plate to the base plate 180.

The flexure 206 allows motion of the disk 204 in both the x and y directions (i.e., in the x/y plane) when a lateral force is applied to the disk 204 by the distal end 168 of the lift pin 170. The flexure 206 additionally acts as a spring to center the disk 204 relative to the outer ring 202, so that the recess 188 may return to a position substantially aligned with the distal end 168 of the lift pin 170 once the substrate support 104 is sufficiently elevated to clear the distal ends 168 of the lift pins from the wear plate 176.

In one embodiment, the flexure 206 may be fabricated from a material having sufficient spring properties to allow movement and centering of the disk 204 relative to the outer ring 202. In one embodiment, the flexure 206 may be a resilient polymer or spring. In another embodiment, the outer ring 202, the disk 204 and the flexure 206 are fabricated from a single, unitary mass of material having a plurality of cut-outs 216, 218 which define the flexure 206 therebetween in a configuration that has sufficient spring properties to center and allow translation of the disk 204 relative to the outer ring 202. In one embodiment, the outer ring 202, the disk 204 and the flexure 206 are fabricated from a single, unitary mass of polymer. Suitable polymers may be selected to be compatible with processes performed in the processing system 100 while having sufficient mechanical properties to allow sliding and centering of the contact plate 182 relative to the base plate 180. In one embodiment, the contact plate 182 is fabricated from a fluoropolymer, such as TEFLON®, high density polyethylene or other suitable polymer.

In the embodiment depicted in FIG. 2, the cut-outs 216, 218 formed in the contact plate 182 define a flexure 206 comprised of an intermediate ring 210 which is coupled to the outer ring 202 by outer webs 212 and coupled to the disk 204 by inner webs 214. The relative size of the cut-outs 216, 218, the intermediate ring 210 and the webs 212, 214 defining the flexure 206 along with the thickness and mechanical properties of the contact plate 182 may be selected to provide the appropriate lateral travel and centering of the recess 188.

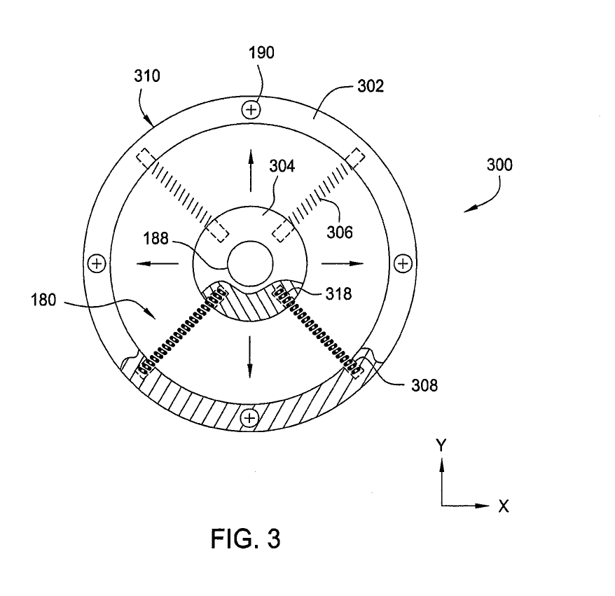

FIG. 3 depicts another embodiment of a wear plate 300. The wear plate 300 includes a contact plate 310 coupled to a base plate 180 by fasteners 190. The contact plate 310 includes an outer ring 302 circumscribing a disk 304. The disk 304 includes the recess 188 formed on its upper surface. A biasing member, shown in FIG. 3 as a plurality of springs 306, is disposed in a polar array between the disk 304 and the outer ring 302, thereby allowing translation of the disk 304 relative to the outer ring 302 in both the x and y directions. In one embodiment, the disk 304 includes a plurality of blind holes 318 for receiving one end of the spring 306, while the outer ring 302 includes a plurality of blind holes 308 for receiving the second end of the spring 306.

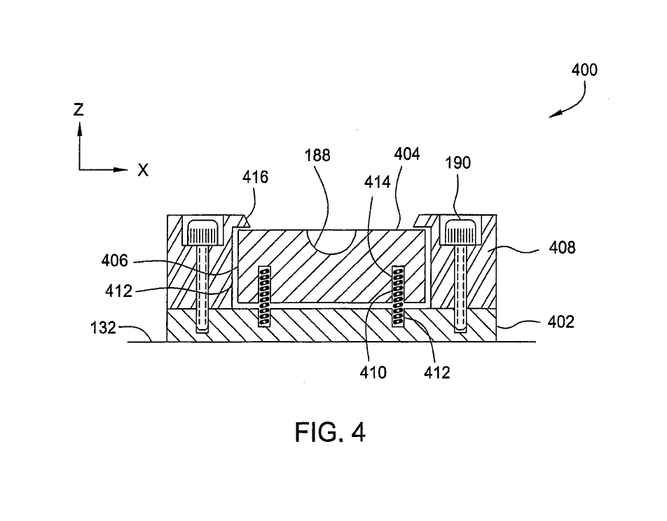

FIG. 4 is a sectional view of another embodiment of a wear plate 400. The wear plate 400 includes a base plate 402, upon which a contact plate 404 translates in the x and y direction. A biasing member is utilized to return the contact plate 404 to a centered position relative to the base plate 402 after displacement. In the embodiment depicted in FIG. 4, the biasing member is shown as a plurality of springs 410. The plurality of springs 410 float the contact plate 404 above the surface of the base plate 402. The springs 410 may be orientated in a substantially vertical orientation (along the z axis), such that the recess 188 formed in the upper surface of the contact plate 404 is urged to a centered position upon the removal of a force applied to the contact plate 404. In one embodiment, a retainer 408 is coupled to the base plate 402 by fasteners 190. The retainer includes a lip 416 which extends over the upper surface of the contact plate 404 to retain the contact plate 404 above the base plate 402. Sufficient clearance is provided between the side 412 of the retainer 408 and the side 406 of the contact plate 404 to allow a pre-defined translation of the contact plate 404 that accommodates the movement of the distal end 168 of the lift pin 170.

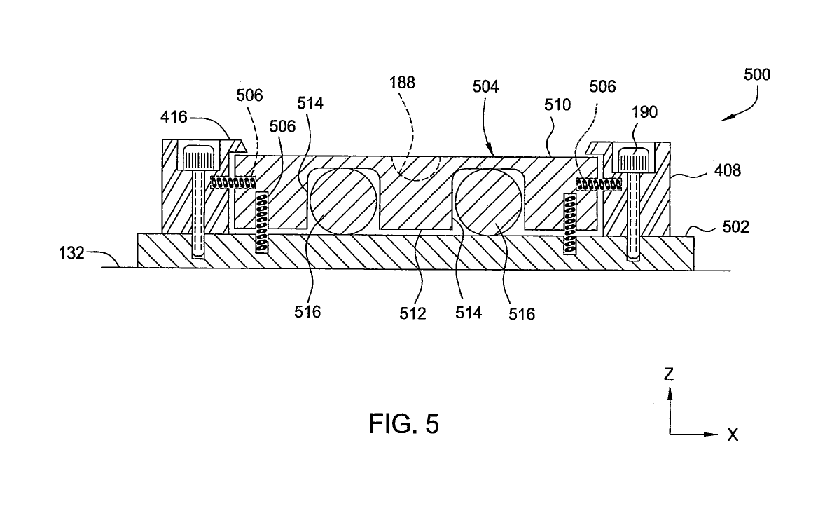

FIG. 5 is a sectional view of another embodiment of a wear plate 500. The wear plate 500 includes a base plate 502 and a contact plate 504. The contact plate 504 includes a top surface 510 for contacting the distal end 168 of the lift pins 170 and a bottom surface 512 facing the base plate 502. The top surface 510 may optionally include a recess 188. A biasing member is provided to allow translational motion of the contact plate 504 in the x and y directions relative to the base plate 502. In the embodiment depicted in FIG. 5, the biasing member is illustrated as a plurality of springs 506.

The springs 506 additionally function to center the contact plate 504 above the base plate 502 when force is removed from the contact plate 504. In one embodiment, the springs 506 are orientated in a substantially vertical direction between the base plate 502 and the contact plate 504. In another embodiment, the springs 506 may be disposed between the retainer 408 and the contact plate 504 (as shown in phantom) in a polar array arranged in the x/y plane.

In the embodiment depicted in FIG. 5, a plurality of rollers 516 are disposed between the base plate 502 and the contact plate 504 to facilitate motion of the contact plate 504 in the x/y plane. The rollers 516, for example ceramic or stainless steel balls, are retained in pockets 514 formed in the bottom surface 512 of the contact plate 504. In one embodiment, the pockets 514 are blind holes having a diameter larger enough to allow the contact plate 504 to translate laterally over the base plate 502.

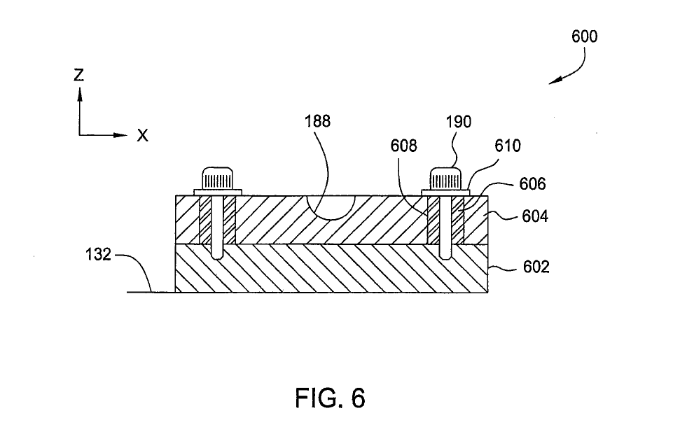

FIG. 6 depicts another embodiment of a wear plate 600. The wear plate 600 includes a base plate 602 and a contact plate 604. Holes 608 formed through the contact plate 604 which accommodate fasteners 190 coupling the contact plate 604 to the base plate 602 are sleeved with a resilient material 606. A washer 610 may be utilized to retain the resilient material 606 in the hole 608. The resilient material 606 is generally a tube or a ring fabricated from an elastomeric material compatible with the processing environment inside the processing system 100. In one embodiment, the resilient material is VITON®. The resilient material 606 is selected to provide sufficient translation of the contact plate 604 in the x/y plane to accommodate the lateral motion of the lift pin 170, while having sufficient resiliency to return the contact plate 604 to a centered position relative to the base plate 602 once force of the lift pin 170 is removed from the contact plate 604.

FIGS. 7 and 8 are sectional and bottom views of one embodiment of lift pin guide 174. The lift pin guide 174 includes a generally cylindrical body 702 having a central bore 708 and an outwardly extending flange 704. A portion 750 of the body 702 extends below a bottom surface 740 of the substrate support 104. An enlarged end 752 of the portion 750 of the body 702 that extends below the bottom surface 740 of the substrate support 104 may include flats 802 to assist in orientating the body 702 and removing the body 702 from the stepped hole 760 formed in the substrate support 104 which receives the body 702 of the lift pin guide 174. The flange 704 includes a plurality of mounting holes 706 which accommodate fasteners 730 which couple the body 702 to the substrate support 104. A plurality of bushings are disposed in the bore 708 and provide a bearing surface for the shaft 164 of the lift pin 170. In the embodiment depicted in FIG. 7, bushings 710 and 720 are illustrated.

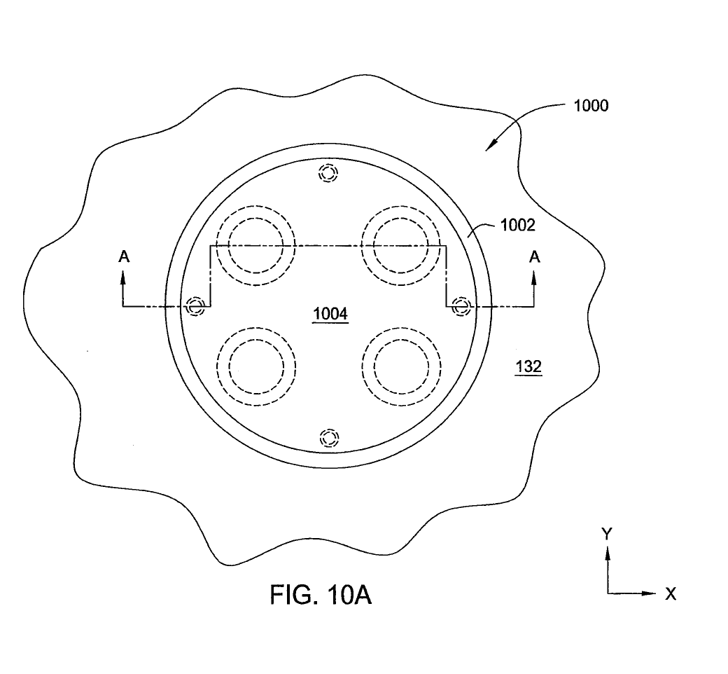

Referring additionally to the isometric view of the bushing illustrated in FIG. 9, the bushings 710 and 720 respectively include cylindrical sleeves 712, 722 having radially extending lips 714, 724. The lips 714, 724 have a tapered outer surface 904 to facilitate entry into the bore 708 of the body 702. The lips 714, 724 engage annular grooves 716, 726 formed in the bore 708 such that the bushing 710, 720 snap-fit into the bore 708 of the body 702. Optionally, to improve the snap-fit and easy of insertion, one or more slits 906 may be formed through the lip and sleeve to enhance the spring action. The snap-fit prevents the bushings 710, 720 from falling out of the bore 708. The bushings 710, 720 include a head 718, 728 which prevent the lips 714, 724 from being inserted past the grooves 716, 726.

Since the first bushing 710 is retained at the first end of the body 702 proximate the upper surface 140 of the substrate support 104 and the second bushing 720 is retained in the portion 750 of the body 702 that extends below the bottom surface 740 of the substrate support 104, the spacing between the bushings 710, 720 may exceed the thickness of the substrate support 104. The wide spacing of the bushings 710, 720 reduces the stress upon the bushings by spreading the bearing surfaces (i.e., the portion of the bore 902 of the bushings 710, 720 in contact with the lift pins 170). In one embodiment, bushings 710, 720 may be spaced up to 3 inches apart to reduce stress on the lift pins 170.

Additionally, since only one end of the bushings 710, 720 is locked to the body 702, the sleeves 712, 722 may freely expand when heated without damage to the bushings 710, 720. Additionally, the snap-fit maintains the bushings 710, 720 in a spaced-apart relation such that the sleeves 712, 722 of the bushings 710, 720 do not touch, thus accommodating thermal expansion of the bushings 710, 720 without buckling the sleeves 712, 722, which could bind the shafts 164 of the lift pins 170.

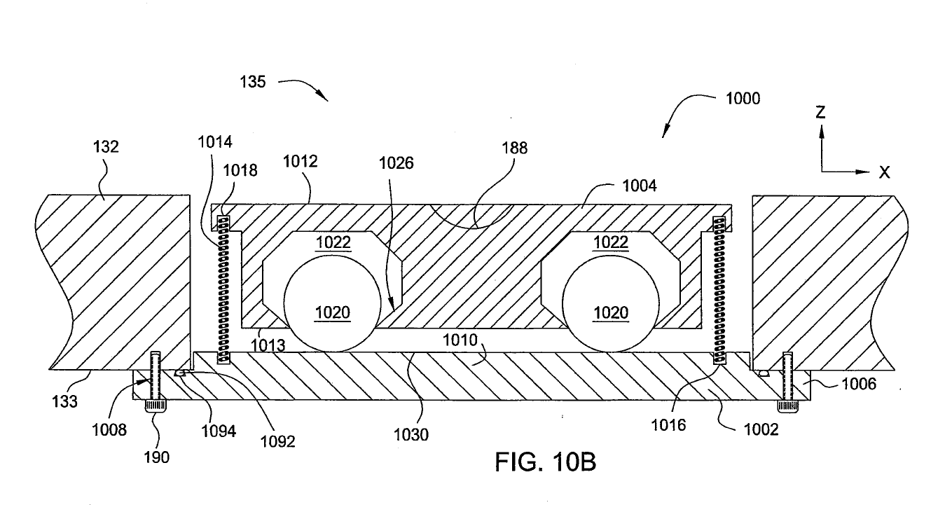

FIG. 10A is a top view of another embodiment of a wear plate 1000, and FIG. 10B is a cross-sectional view of the wear plate 1000 taken along section A-A. The wear plate 1000 includes a base plate 1002 and a contact plate 1004. A biasing member is provided to control the movement of the contact plate 1004 relative to the base plate 1002.

In one embodiment, the base plate 1002 is in the general shape of a plug having a flange 1006 with a plurality of holes 1008 extending therethrough for coupling the base plate 1002 to an outer bottom surface 133 of the bottom 132 of the chamber body 102 via fasteners 190. A seal 1092 is disposed in a groove 1094 formed in the flange 1006 to prevent leakage. The wear plate 1000 may include a central plug region 1010 extending vertically from the flange 1006, which partially extends into a chamber aperture 135 formed through the bottom 132 of the chamber body 102 directly beneath each lift pin 170. In one embodiment, the base plate 1002 is aluminum or stainless steel.

The contact plate 1004 may have a disk or other shape. The contact plate 1004 is disposed in a hole formed in the bottom 132 of the chamber body 102. The contact plate 1004 is smaller than the hole formed in the bottom 132 of the chamber body 102, thereby allowing the contact plate 1004 to displace laterally as further described below.

The contact plate 1004 includes a top surface 1012 for contacting the distal end 168 of the lift pins 170 and a bottom surface 1013 facing the base plate 1002. The top surface 1012 may optionally include a recess 188 (shown in phantom) for receiving the distal end 168 of the lift pins 170. In one embodiment, the contact plate 1004 is comprised of a ceramic material.

A biasing member is provided between the base plate 1002 and the contact plate 1004 to float the contact plate 1004 above the surface of the base plate 1002. The biasing member may be as described above, such as a plurality of springs 1014 as illustrate in FIG. 10B. In one embodiment, the base plate 1002 includes a plurality of blind holes 1016 for receiving one end of the spring 1014, while the contact plate 1004 includes a plurality of blind holes 1018 for receiving the other end of the spring 1014. The springs 1014 may be configured in a substantially vertical orientation (along the z axis), such that the contact plate 1004 is urged to a centered position upon the removal of a force applied to the contact plate 1004. Thus, the springs 1014 allow the contact plate 1004 to move both vertically along the z axis and laterally in the x-y plane relative to the base plate 1002.

In the embodiment depicted in FIG. 10, the springs 1014 are illustrated as compression springs. However, it is contemplated that the springs 1014 may be one or more potential energy storing elements, such as coil springs, flat springs, spring forms, flexures, elastomeric members or other member suitable to return to contact plate 1004 to a centered position upon the removal of a force sufficient to displace the contact plate 1004.

The springs 1014 may also be configured to retain the contact plate 1004 to the base plate 1002. For example, the ends of the springs 1014 may be captured in, clamped, bonded or otherwise retained in the holes 1016, 1018. Alternatively, a retainer (not shown), such as retainer 408 described above, may be utilized to retain the contact plate 1004 to the base plate 1002.

In one embodiment, a plurality of rollers 1020 are disposed between the base plate 1002 and the contact plate 1004 to facilitate motion of the contact plate 1004 in the x-y plane. The rollers 1020 may be ceramic or stainless steel balls, which are retained in pockets 1022 formed in the bottom surface 1013 of the contact plate 1004. In one embodiment, each pocket 1022 has a conical seat 1024 for centering, or resetting, the roller 1020 in the respective pocket 1022 when the contact plate 1004 is spaced from the base plate 1002 upon removal of a force applied to the contact plate 1004.

In one embodiment, the pockets 1022 are blind holes having a orientation substantially perpendicular to the bottom surface 1013 of the contact plate 1004. The pockets 1022 have a diameter larger enough to allow the contact plate 1004 to translate laterally over the base plate 1002. The pockets 1022 have a depth that maintains a least a portion of the rollers 1020 protruding from the pocket 1022 when the roller 1022 is in contact with a top surface of the pocket 1022, while allowing the roller 1022 to be substantially clear of the conical seat 1024.

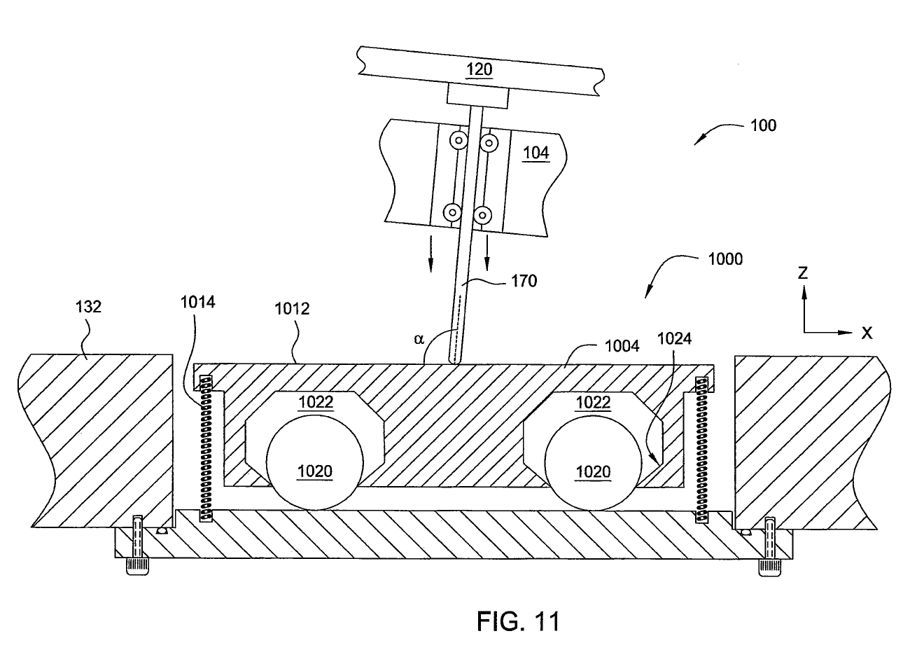

FIG. 11 is a partial cross-sectional view of the processing system 100 having the wear plate 1000 of FIGS. 10A and 10B attached thereto. As shown in FIG. 11, the wear plate 1000 is in an initial, or unloaded, state as the substrate support 104 containing the guide 174 with the lift pin 170 disposed therein, is lowered toward the chamber bottom 132. As can be seen in the embodiment shown, the guide 174 and/or lift pin 170 may be orientated at a non-perpendicular angle α with respect to the top surface 1012 of the contact plate 1004 and chamber bottom 132. In this initial state, no load is yet being applied to the contact plate 1004. As such, the contact plate 1004 is lifted and centered above the base plate 1002 via the springs 1014. Additionally, the rollers 1020 are centered laterally (the x-y plane) within the pockets 1022 by the conical seats 1024. In one embodiment, the rollers 1020 are suspended above the base plate 1002 within the conical seats 1024. In one embodiment, the rollers 1020 are lightly contacting the base plate 1002.

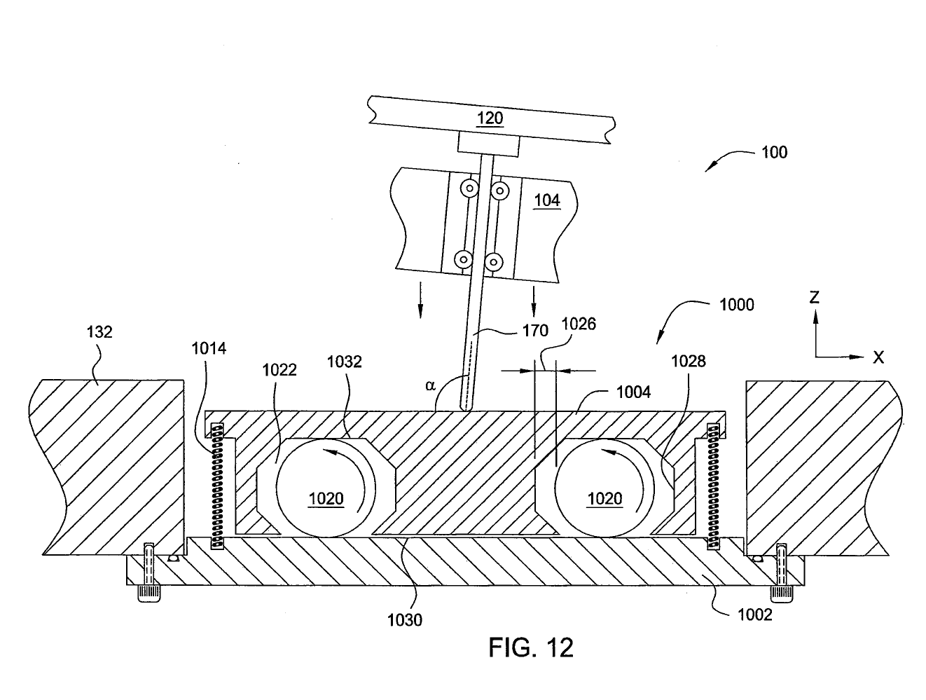

FIG. 12 depicts the processing system 100 illustrated in FIG. 11 in an initial loading state. As shown in FIG. 12, the substrate support 104 from FIG. 11 has been lowered such that the lift pin 170 has made initial contact with the contact plate 1004 of the wear plate 1000. This initial contact, or light loading of the contact plate 1004, causes compression of the springs 1014, in turn, lowering the contact plate 1004 until the rollers 1020 are spaced from the conical seats 1024 and contact the ceiling 1032 of the pockets 1022. Since each roller 1020 is horizontally centered in the pockets 1022 by the conical seats 1024 while the contact plate 1004 is elevated, once the contact plate 1004 is displaced toward the base plate 1002, the seats 1024 clear the rollers 1020, such that the rollers 1020 are spaced from the sidewalls 1028 of the pockets 1022 and are free to roll in any direction by a circumferential gap 1026.

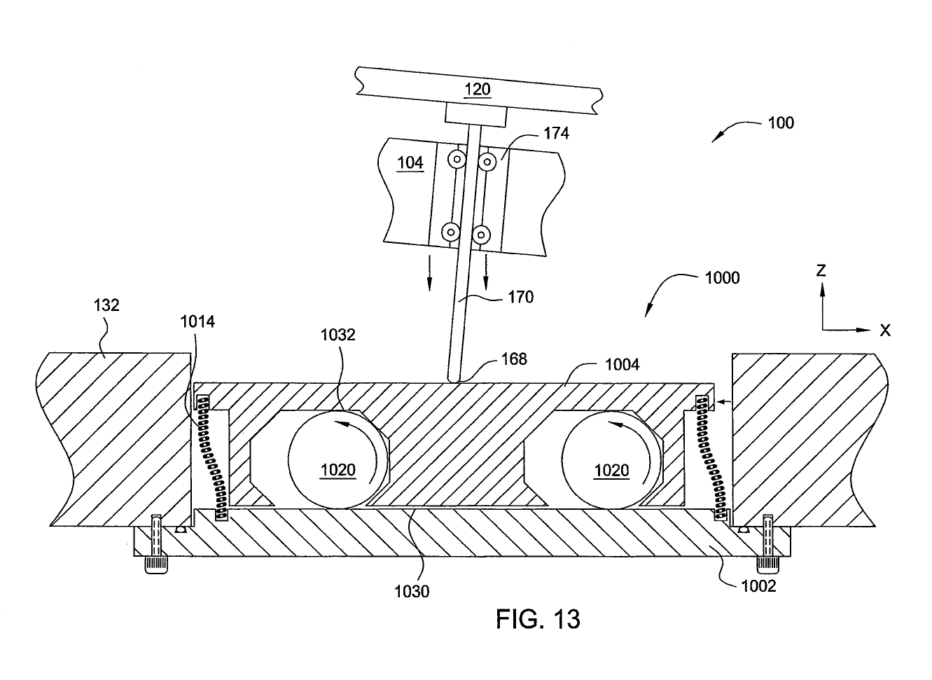

FIG. 13 depicts the processing system 100 illustrated in FIGS. 11 and 12 in an advanced loading state. As shown in FIG. 13, the lift pin 170, loaded by the substrate 120, further loads the contact plate 1004 until the lift pin 170 can not move further downward (in the −z direction). As the substrate support 104 continues to lower the guide 174, the guide, by constraining the shaft of the lift pin 170, forces the contact plate 1004 to roll laterally (in the x-y plane) on the rollers 1020. Since the contact plate 1004 is allowed to roll laterally, the distal end 168 of the lift pin 170 is not forced to drag across the top surface 1012 of the contact plate 1004, minimizing particle contamination. Additionally, because the contact plate 1004 is allowed to roll laterally, side loading on the guide 174 is minimized, resulting in longer life of guide components, such as roller bushing axles.

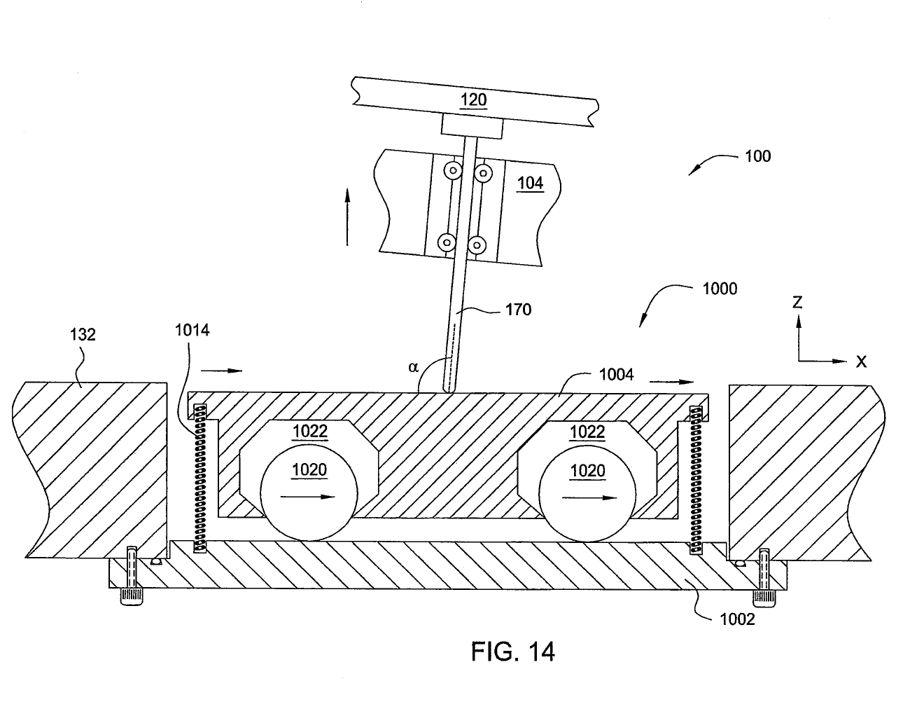

FIG. 14 depicts the processing system 100 illustrated in FIGS. 11, 12, and 13 in an unloading state. As shown in FIG. 14, the substrate support 104 is raised, in turn raising the guide 174 and the lift pin 170. As the lift pin 170 is raised clear of the contact plate 1004, the springs 1014 raise and center the contact plate 1004 over the base plate 1002. Accordingly, as the contact plate 1004 is raised, each roller 1020 comes into contact with the conical seat 1024, which re-centers each roller 1020 laterally (in the x-y plane) within each pocket 1022 to prevent binding of the roller 1020 against the sidewalls 1028 of the pocket 1022 after multiple uses.

Thus, a method and apparatus for processing large area substrates is provided and includes at least one of a translational wear plate and/or bushing assembly which reduces stress on lift pins used to space large area substrates from a substrate support. It is contemplated that the method and apparatus described herein may be used for smaller substrates such as semiconductor wafers as well among other lift pin applications. The translational wear plate and the bushing assemblies have been demonstrated to significantly extend the life of the lift pin mechanisms, thereby reducing the cost of ownership reducing and substrate damage, while increasing system throughput.

While the foregoing is directed to embodiments of the present invention, other and further embodiments of the invention may be devised without departing from the basic scope thereof, and the scope thereof is determined by the claims that follow.

What is claimed is:

1. A processing chamber, comprising:
a chamber body;
a substrate support disposed in the chamber body;
a plurality of lift pins disposed through the substrate support, each lift pin having a head displaceable to an elevation above an upper surface of the substrate support and a distal end extending below the substrate support; and
a plurality of contact plates disposed below the substrate support, each contact plate aligned with a respective lift pin, each contact plate laterally movable relative to the substrate support.

2. The processing chamber of claim 1, wherein each contact plate is biased to a laterally centered position.

3. The processing chamber of claim 2 further comprising:
a plurality of biasing members, at least one biasing member associated with a respective one of the contact plates, the biasing members allowing lateral movement of the contact plates while biasing the contact plate to the laterally centered position.

4. The processing chamber of claim 3, wherein the biasing member allows movement of the contact plate perpendicular to the lateral movement.

5. The processing chamber of claim 1, wherein the contact plates each comprise:
a plurality of pockets having a conical ball seat; and
a plurality of rollers, each roller retained in a respective one of the pockets by the conical ball seat.

6. The processing chamber of claim 5, wherein the rollers are sized to be movable both laterally and vertically in the pocket.

7. The processing chamber of claim 1 further comprising:
a base plate; and
a plurality of springs spacing the contact plate from the base plate.

8. The processing chamber of claim 3, wherein the biasing members are selected from the group consisting of coil springs, flat springs, spring forms, flexures, elastomeric members.

9. A processing chamber, comprising:
a chamber body;
a substrate support disposed in the chamber body;
a plurality of lift pins disposed through the substrate support, each lift pin having a head displaceable to an elevation above an upper surface of the substrate support and a distal end extending below the substrate support;
a plurality of contact plates disposed below the substrate support, each contact plate aligned with a respective lift pin, each contact plate having a plurality of pockets having a conical ball seat;
a plurality of springs supporting the contact plates in an elevated position which allows both vertical and lateral movement of the contact plate; and
a plurality of rollers, each roller retained in a respective one of the pockets of the contact plate by the conical ball seat.

10. The processing chamber of claim 9, wherein each of the contact plates is a disk.

11. The processing chamber of claim 9 further comprising a plurality of base plates coupled to the chamber body, wherein the springs urge each contact plates in a centered position relative to a respective base plate.

12. The processing chamber of claim 9 further comprising a plurality of base plates coupled to the chamber body, wherein the springs urge each contact plates towards a centered position relative to a respective base plate.

13. The processing chamber of claim 12, wherein each base plate and contact plate pair are coupled together by the springs.

14. The processing chamber of claim 9, wherein one of the contact plates is a disk disposed in a hole formed in the chamber body.

15. The processing chamber of claim 14, wherein hole formed in the chamber body is sealed by a base plate.

16. The processing chamber of claim 14, wherein base plate is coupled to the contact plate by the springs.

17. A method for spacing a substrate from a substrate support, comprising:
lowering a substrate support to contact distal ends of lift pins to a laterally movable wear plate; and
further lowering the substrate support to project heads of the lift pins contacting the wear plate from an upper surface of the substrate support, wherein the wear plate is displaced laterally by the distal ends of lift pins.

18. The method of claim 17 further comprising:
raising the substrate support until contact between the wear plate with the distal ends of lift pins is removed, wherein the wear plate is displaced to a centered position once free from contact with the lift pins by a biasing member.

19. A processing chamber comprising:
a chamber body;
a substrate support disposed in the chamber body;
a bushing assembly disposed in the substrate support;
a lift pin disposed through the bushing assembly; and
a wear plate coupled to the chamber body and aligned with the lift pin, wherein the wear plate is movable laterally relative to a centerline of the chamber body.

20. A processing chamber comprising:
a chamber body;
a substrate support disposed in the chamber body;
a bushing assembly disposed in the substrate support; and
a lift pin disposed through the bushing assembly, wherein the bushing assembly comprises:
a cylindrical body having central bore; and
a plurality of bushings snap-fit into the central bore.
